(19) United States
(12) Patent Application Publication
(10) Pub. No.: US 2026/0051854 A1
(43) Pub. Date: Feb. 19, 2026

(54) LINEAR AMPLIFIER OUTPUT STAGE CORRECTION CIRCUIT

(71) Applicant: Garmin International, Inc., Olathe, KS (US)

(72) Inventor: Todd A. Eichenbaum, Oxford, CT (US)

(21) Appl. No.: 18/800,883

(22) Filed: Aug. 12, 2024

(51) Int. Cl. H03F 1/34

(52) U.S. Cl. CPC H03F 1/34; H03F 2200/03

(57) ABSTRACT

A linear amplifier with correction circuit is provided. According to one aspect, a linear amplifier includes a high current output stage configured to produce an output voltage and current to deliver power to a load. An output correction circuit receives the output voltage from the high current output stage and produces an error current proportional to a voltage drop across the high current output stage. An input stage receives at least one input and produces a first input current. A current-to-voltage resistor receives produces a first voltage that depends on the first input current and the error current. A first unity gain voltage buffer receives the first voltage from the current-to-voltage resistor and outputs a second voltage that is input to the high current output stage. The first voltage is compensated by the error current to reduce the voltage drop across the high current output stage.

### TECHNICAL FIELD

The present invention relates to amplifiers and in particular to a linear amplifier having an output stage correction circuit.

### BACKGROUND

A linear amplifier is used in applications where an output signal that is linearly proportional to the input signal is desirable or required. Such applications include audio amplifiers such as may be used in home or mobile audio/multimedia systems.

### BRIEF DESCRIPTION OF THE DRAWINGS

FIG. 1 is a block diagram of a known linear amplifier;

FIG. 2 is a block diagram of one example of a linear amplifier with a first example output correction block;

FIG. 3 is a block diagram of one example of a linear amplifier with first example output correction block and feedback circuitry;

FIG. 4 is a block diagram of one example of a linear amplifier with a second example output correction block and feedback circuitry;

FIG. 5. is a block diagram of one example of a linear amplifier with a first output correction block, feedback circuitry and a differential current conveyor input stage;

FIG. 6 is a block diagram of one example of a linear amplifier with a second output correction block, feedback circuitry and a differential current conveyor input stage; and

FIG. 7 is a block diagram of another example embodiment of a linear amplifier having a correction block with an operational transconductance amplifier.

### DETAILED DESCRIPTION

Before describing in detail exemplary embodiments, it is noted that the embodiments reside primarily in combinations of apparatus components related to linear amplification with output correction. Accordingly, components have been represented where appropriate by conventional symbols in the drawings, showing only those specific details that are pertinent to understanding the embodiments so as not to obscure the disclosure with details that will be readily apparent to those of ordinary skill in the art having the benefit of the description herein. Like numbers refer to like elements throughout the description.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate and modifications and variations are possible of achieving the electrical and data communication.

In some embodiments described herein, the term “coupled,” “connected,” and the like, may be used herein to indicate a connection, although not necessarily directly, and may include wired and/or wireless connections.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

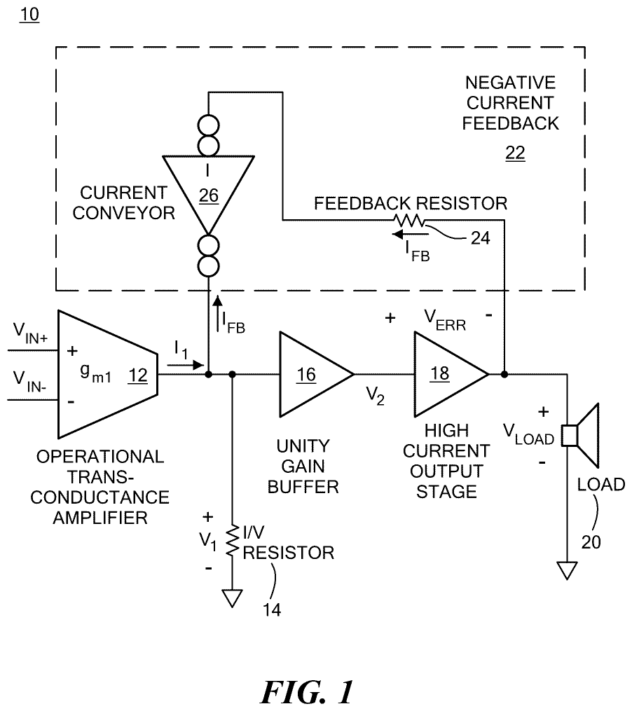

Referring now to the drawing figures in which like reference designators refer to like elements, FIG. 1 shows a block diagram of a linear amplifier circuit 10 with negative feedback. An input stage 12 may be configured with an operational transconductance amplifier to provide an output current I₁ equal to a transconductance factor, gₘ₁, times a differential input voltage (V_{IN+}−V_{IN-}). The input stage may be assumed to be ideal. At the output of the input stage 12 is a current to voltage (I/V) resistor R_{IV} 14 that is configured to convert the current I₁ (minus a feedback current I_{FB}) to an amplified signal voltage V₁. A unity-gain voltage buffer 16, assumed to be ideal, outputs a voltage V₂ that is exactly equal to its input voltage V₁ developed across the I/V resistor R_{IV} 14. Because the unity gain voltage buffer 16 is not under a heavy load, the assumption of ideal behavior is valid. A high current output stage 18 provides an output voltage to the load 20. If the high current output stage 18 were ideal, then the voltage across load 20, V_{LOAD}, would be exactly equal to its input voltage V₂ regardless of the load impedance of the load 20. However, the high current output stage is not ideal. V₂ differs from V_{LOAD} by the amount V_{ERR}.

The open loop (i.e., without the negative current feedback circuit 22) gain equations for the circuit of FIG. 1 are given by:

V₁=gₘ₁(V_{IN+}−V_{IN-})R_{IV}

V₂≈V₁

V_{LOAD}=V₂−V_{ERR}≈gₘ₁(V_{IN+}−V_{IN-})R_{IV}−V_{ERR}

In other words, the output voltage at the load is equal to the differential input voltage times gₘ₁·R_{IV} minus the error voltage V_{ERR} resulting from the nonideal behavior of the output stage.

FIG. 1 also shows a negative current feedback circuit 22 that includes a feedback resistor 24 and an inverting current conveyor 26. The feedback resistor 24 produces a feedback current I_{FB} that is equal to the load voltage V_{LOAD} divided by the resistance R_{FB} of the feedback resistor 24. The inverting current conveyor 26 inverts the polarity of the feedback current I_{FB}. The feedback current I_{FB} is subtracted from the output current I₁ from the input stage 12.

The resulting closed-loop gain equations, taking into account the negative current feedback circuit 22, are given by:

V₁=[gₘ₁(V_{IN+}−V_{IN-})−(V_{LOAD}/R_{FB})]·R_{IV}

As explained above, V_{LOAD}=V₂−V_{ERR}≈V₁−V_{ERR}. Using this result gives:

V_{LOAD}≈V₁−V_{ERR}=gₘ₁(R_{IV}||R_{FB})(V_{IN+}−V_{IN-})−[R_{FB}/(R_{FB}+R_{IV})]V_{ERR}

In other words, the two terms comprising the load voltage are (1) the differential input voltage times gₘ₁ times the parallel combination of R_{IV} and R_{FB} and (2) an error voltage that is reduced from the open-loop case described above by a factor of R_{FB}/(R_{FB}+R_{IV}). Therefore, adding negative feedback reduces the signal gain and decreases the effective error voltage at the load.

In order to completely eliminate any output stage error voltage from the load voltage using only negative feedback, as shown in FIG. 1, the second term (the reduced voltage error) must be zero:

R_{FB}/(R_{FB}+R_{IV})=0

This implies the following:

R_{FB}=0, or R_{IV}=∞

But if R_{FB}=0, the magnitude of the closed-loop differential input gain [=gₘ₁ (R_{IV}||R_{FB})] will also be 0, making the amplifier useless. Conversely, setting R_{IV} to something extremely large (→∞) will result in very high open-loop gain [=gₘ₁·R_{IV} from before]. This would require large feedback to achieve the desired closed-loop gain. This may have undesirable effects on the performance of linear amplifier 10, while still not completely eliminating output-stage-error.

In some examples, a correction circuit for an amplifier is provided that corrects for a voltage drop across a high current output stage of a linear amplifier. A purpose of correcting for the voltage drop across the high current output stage is to ensure that the output of the high current output stage is linearly proportional to an input to the linear amplifier. This is useful, for example, in audio amplifiers to amplify an audio signal without distortion before being converted to sound waves by a speaker.

In some examples, the voltage drop across the high current output stage is input to an amplifier to feed back an error current that offsets an input signal to exactly compensate for the voltage drop across the high current output stage. By feeding back the error current to offset the input signal, the voltage drop across the high current output stage is cancelled. In some embodiments, the voltage drop across the high current output stage is converted to an error current that is fed back using a current mirror.

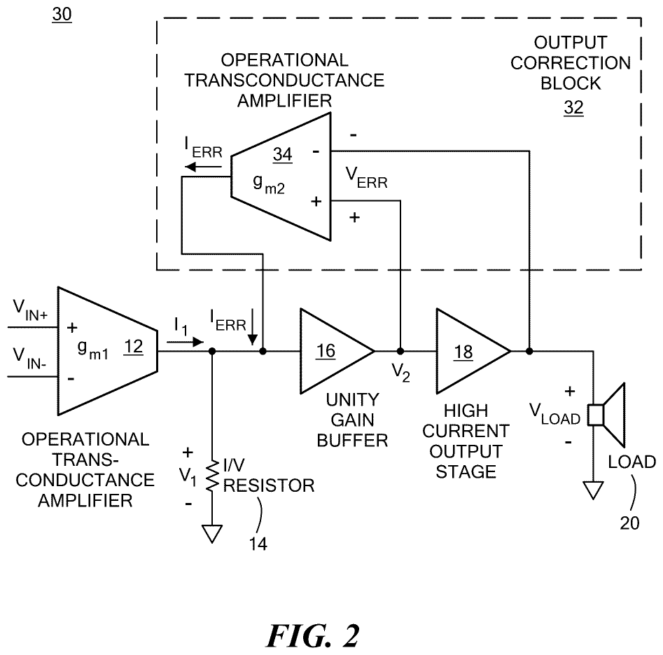

FIG. 2 is a block diagram of one example of a linear amplifier 30 including an output correction block 32 constructed according to principles disclosed herein. The linear amplifier 30 may be configured to include an input stage 12, I/V resistor 14, unity gain buffer 16, and the high current output stage 18, which is shown connected to the load 20. The output correction block 32 includes an operational transconductance amplifier 34, which receives the voltage V_{ERR} taken across the high current output stage 18, and outputs an error current I_{ERR}. The error current I_{ERR} is equal to the transconductance gₘ₂ times the output stage error voltage V_{ERR.} The error current I_{ERR} is added to the current I₁ that is output from the input stage 12.

The open-loop gain equations with output stage correction block 32 may be written as:

V₁=[gₘ₁(V_{IN+}−V_{IN-})+gₘ₂ V_{ERR}]R_{IV}

V_{LOAD}≈V₁−V_{ERR}=[gₘ₁(V_{IN+}−V_{IN-})+gₘ₂ V_{ERR}]R_{IV}−V_{ERR}

Observe that if gₘ₂=1/R_{IV} (so that gₘ₂ R_{IV}=1), the last two terms cancel, eliminating any contribution from the output stage error voltage in the load voltage V_{LOAD}. In other words, the load voltage becomes strictly the amplified differential input voltage:

V_{LOAD}=gₘ₁ R_{IV}(V_{IN+}−V_{IN-})

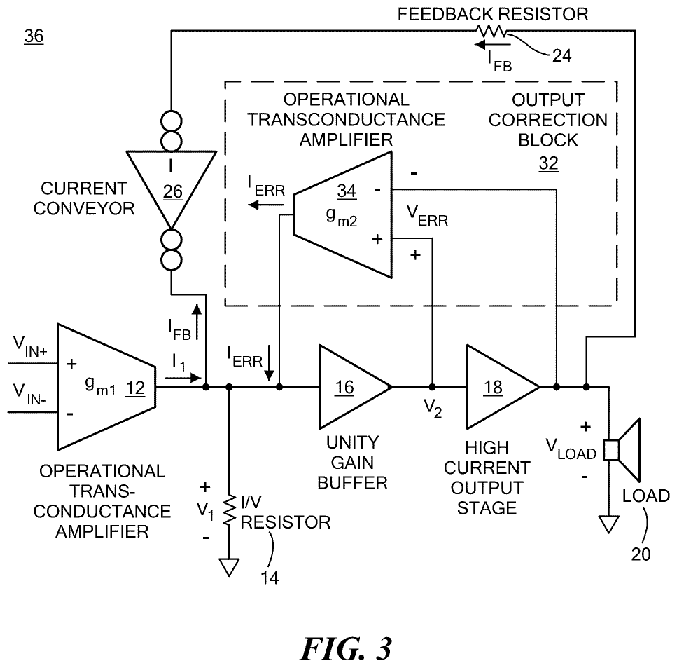

FIG. 3 is a block diagram of another example of a linear amplifier 36 with output correction block 32, constructed according to principles disclosed herein. The linear amplifier 36 includes the output correction block 32 of FIG. 3 and includes the feedback resistor 24 and current conveyor 26 of FIG. 1.

The closed-loop gain equations of the linear amplifier 36 may be written as:

V₁=[gₘ₁(V_{IN+}−V_{IN-})+gₘ₂V_{ERR}−(V_{LOAD}/R_{FB})]R_{IV}

As before, substitute V_{LOAD}≈V₁−V_{ERR}, and the resulting equation is:

V₁=gₘ₁(R_{IV}||R_{FB})(V_{IN+}−V_{IN-})+(R_{IV}||R_{FB})[gₘ₂+(1/R_{FB})]V_{ERR}, and

V_{LOAD}=gₘ₁(R_{IV}||R_{FB})(V_{IN+}−V_{IN-})+(R_{IV}||R_{FB})[gₘ₂+(1/R_{FB})]V_{ERR}−V_{ERR}

To eliminate any contribution to the load voltage V_{LOAD} from the high current output stage error voltage V_{ERR}, gₘ₂ may be chosen such that the last two terms cancel. In other words:

(R_{IV}||R_{FB})[gₘ₂+(1/R_{FB})]=1, or

[(R_{IV}·R_{FB})/(R_{IV}+R_{FB})]·[(gₘ₂R_{FB}+1)/R_{FB}]=1

Once again, setting gₘ₂=1/R_{IV} solves this equation and cancels any V_{ERR} terms in the load voltage. Significantly, adding the output correction circuit 32 and setting its transconductance as above not only eliminates any output stage error voltage contribution, but does so independently of the amplifier's signal gain or the amount of negative feedback via the feedback resistor 24.

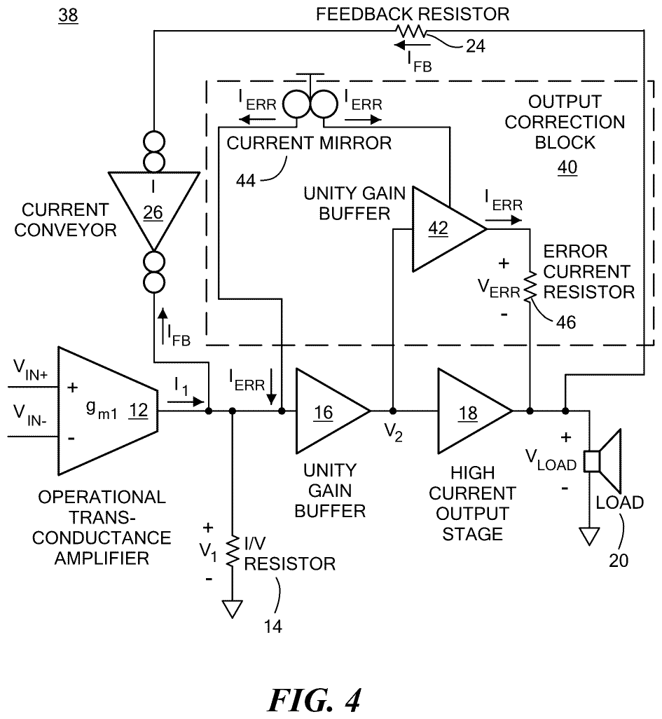

FIG. 4 is a block diagram of another example of a linear amplifier 38 with an output correction block 40. The output correction block includes a unity gain buffer 42, a current mirror 44, and an error current resistor 46. In FIG. 4, the operational transconductance stage 34 that monitors the error voltage V_{ERR} in FIG. 3 is replaced by the unity gain buffer 42, current mirror 44, and error current resistor 46. The output current of the unity gain buffer 42 is defined by the high current output stage error voltage V_{ERR} and an error current resistor R_{EC} 46; this output current is equal to the error current I_{ERR}. The current mirror 44 replicates this error current and sends it to current-to-voltage resistor R_{IV} 14, where it adds to the input stage output current I₁ minus the feedback current I_{FB}. Setting the value of error current resistor R_{EC} 46 equal to the value of current-to-voltage resistor R_{IV} 14 will cancel any error voltage V_{ERR} present in the load voltage V_{LOAD}.

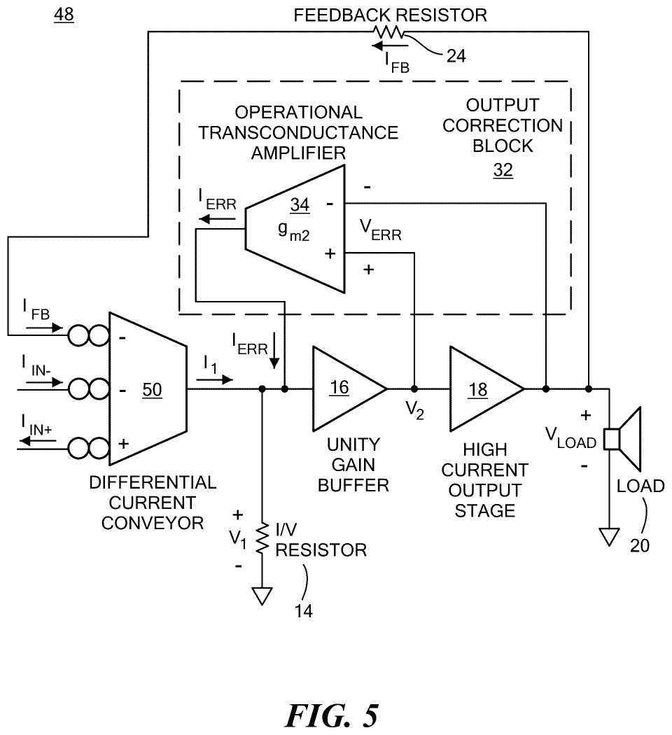

FIG. 5 is a block diagram of another example linear amplifier 48 with the output correction block 32 and feedback resistor 24. Instead of the operational transconductance amplifier of the input stage 12, the linear amplifier includes as an input stage 50, a differential current conveyor. The differential current conveyor of input stage 50 receives as inputs, a differential input current (I_{IN+}−I_{IN-}) and the feedback current I_{FB} from the feedback resistor R_{FB} 24. This configuration is useful when the input signal to be amplified by the linear amplifier 48 is a differential current, rather than a voltage.

Closed-loop gain equations (similar to the equations for FIG. 3) with output stage correction block 32 may be written as:

V₁=[(I_{IN+}−I_{IN-})+gₘ₂V_{ERR}−(V_{LOAD}/R_{FB})]R_{IV}

As before, substitute V_{LOAD}≈V₁−V_{ERR}, and the resulting equation is:

V₁=(R_{IV}||R_{FB})(I_{IN+}−I_{IN-})+(R_{IV}||R_{FB})[gₘ₂+(1/R_{FB})]V_{ERR}, and

V_{LOAD}=(R_{IV}||R_{FB})(I_{IN+}−I_{IN-})+(R_{IV}||R_{FB})[gₘ₂+(1/R_{FB})]V_{ERR}−V_{ERR}

As with the linear amplifier 36 of FIG. 3, setting gₘ₂=1/R_{IV} cancels any V_{ERR} terms in the load voltage.

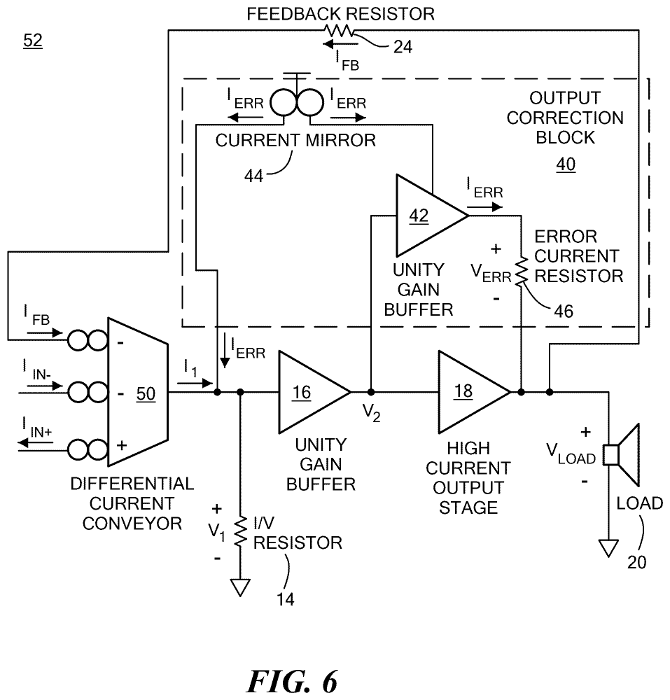

FIG. 6 is a block diagram of another example of a linear amplifier 52 with the output correction block 40, the differential current conveyor 50 and the feedback resistor 24. The differential current conveyor receives the input signal and feedback currents as in the linear amplifier 48 of FIG. 5. The unity gain buffer 42 and error current resistor 46 provide the error correction current I_{ERR}. The configuration of FIG. 6 may be useful, as with FIG. 5, when the input signal to be amplified is a differential current, rather than a voltage.

Closed-loop gain equations with output stage correction block 40 are the same as for the embodiment of FIG. 5, but with the error correction current equal to V_{ERR} divided by the resistance of the error current resistor R_{EC} 46, as in FIG. 4:

V₁=[(I_{IN+}−I_{IN-})+(V_{ERR}/R_{EC})−(V_{LOAD}/R_{FB})]R_{IV}

As before, substitute V_{LOAD}≈V₁−V_{ERR}, and the resulting equation is:

V₁=(R_{IV}||R_{FB})(I_{IN+}−I_{IN-})+(R_{IV}||R_{FB})[(1/R_{EC})+(1/R_{FB})]V_{ERR}, and

V_{LOAD}=(R_{IV}||R_{FB})(I_{IN+}−I_{IN-})+(R_{IV}||R_{FB})[(1/R_{EC})+(1/R_{FB})]V_{ERR}−V_{ERR}

Setting R_{EC}=R_{IV} cancels any V_{ERR} terms in the load voltage.

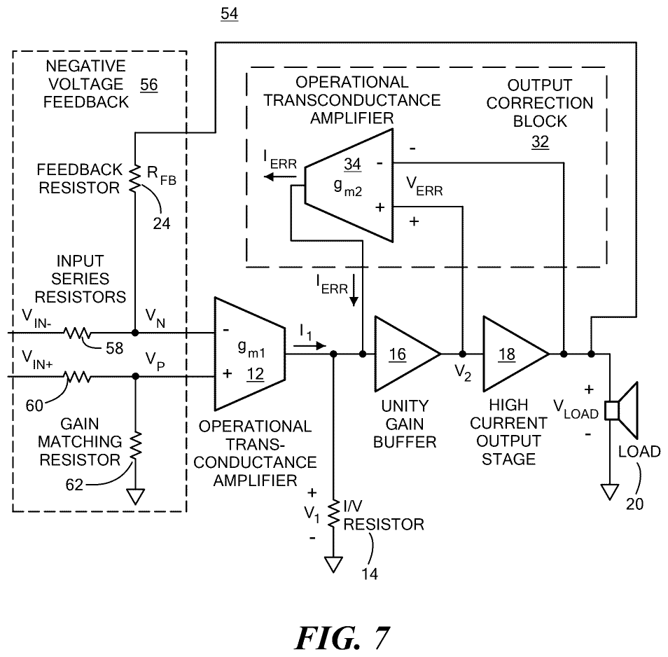

FIG. 7 is another example embodiment of a linear amplifier 54 with the correction block 32 having the operational transconductance amplifier 34, as shown in FIG. 3. However, instead of feeding the feedback current to the current conveyor 26, the feedback resistor 24, in conjunction with input series resistor 58, forms a voltage divider which provides a voltage feedback signal to an inverting input of the operational transconductance amplifier 34. In addition to providing the feedback signal, the negative voltage feedback circuit 56 uses the first input series resistor 58 as well as a second input series resistor 60 for receiving a differential input voltage, (V_{IN+}−V_{IN-}). The negative voltage feedback circuit 56 also includes a gain matching resistor 62, which forms a voltage divider with the second input series resistor 60 to match the overall gain magnitude of V_{IN+} to V_{IN-}.

The feedback resistor R_{FB} 24 is connected between the output and the node shared by the first input series resistor 58 and an inverting input of the operational transconductance amplifier 12. The voltage V_{N} at an inverting input of the operational transconductance amplifier 12 is a voltage that depends upon the voltage drop across the feedback resistor R_{FB} 24 and also depends upon the voltage V_{IN-} that is input via the first input series resistor 58.

The gain matching resistor 62 is connected between ground and the node shared by the second input series resistor 60 and a noninverting input of the operational transconductance amplifier 12. The voltage V_{P} at a noninverting input of the operational transconductance amplifier 12 is a voltage that depends upon the voltage drop across the matching gain matching resistor 62 and also depends upon the voltage V_{IN+} that is input via the second input series resistor 60.

The voltages V_{P} and V_{N} developed at the inputs of the operational transconductance amplifier 12, based on the input voltages V_{IN-} and V_{IN+} and the voltages across the feedback resistor R_{FB} 24 and gain matching resistor 62, provide another method of negative feedback, offering performance and benefits similar to the current-based feedback used in previous examples.

The example linear amplifier 54 of FIG. 7 is similar to the example linear amplifier 36 of FIG. 3, except the negative current feedback is replaced by negative voltage feedback provided by the negative voltage feedback circuit 56. In the circuit of FIG. 7, the signal gain and feedback are determined by the two input series resistors 58 and 60, connected from the input voltage signals V_{IN+} and V_{IN-} to the amplifier's noninverting and inverting voltage inputs; the feedback resistor 24; and the gain matching resistor 62.

In the following analysis, the input series resistors 58 and 60 are assumed to have the same value, both R_{IN}, as are the feedback resistor 24 and gain setting resistor 62, both R_{FB}. This configuration yields the same magnitude of signal gain for both V_{IN+} and V_{IN-}, as will be demonstrated below.

Closed-loop gain equations excluding the output stage correction:

V_{P}=[R_{FB}/(R_{IN}+R_{FB})]V_{IN+}

V_{N}=V_{LOAD}+[R_{FB}/(R_{IN}+R_{FB})][V_{IN-}−V_{LOAD}]

V₁=I₁R_{IV}=gₘ₁(V_{P}−V_{N})R_{IV}

As before, substituting V_{LOAD}≈V₁−V_{ERR}, and combining the three foregoing equations yields:

V_{LOAD}=gₘ₁{[R_{FB}/(R_{IN}+R_{FB})]V_{IN+}−V_{LOAD}−[R_{FB}/(R_{IN}+R_{FB})]V_{IN-}++[R_{FB}/(R_{IN}+R_{FB})]V_{LOAD}}R_{IV}−V_{ERR}

Rearranging terms in the above yields:

V_{LOAD}=[(gₘ₁R_{FB}R_{IV})/(R_{IN}+R_{FB})][V_{IN+}−V_{IN-}]+[(gₘ₁R_{IN}R_{FB})/(R_{IN}+R_{FB})]V_{LOAD}−V_{ERR}

Regrouping terms in the above yields:

V_{LOAD}=[(gₘ₁R_{FB}R_{IV})/(R_{IN}+R_{FB}+gₘ₁R_{IN}R_{IV})][V_{IN+}−V_{IN-}]−[(R_{IN}+R_{FB})/(R_{IN}+R_{FB}+gₘ₁R_{IN}R_{IV})]V_{ERR}

From this it can be observed that, as the open-loop voltage gain of the amplifier (=gₘ₁R_{IV}) increases, the closed-loop signal gain of the amplifier approaches R_{FB}/R_{IN}, and the contribution of V_{ERR} is reduced. Although the exact numbers are slightly different, the end result is functionally the same as the negative current feedback example of FIG. 3.

The closed-loop gain equations including the output stage correction:

V₁=(I₁+I_{ERR})R_{IV}=[gₘ₁(V_{P}−V_{N})+gₘ₂V_{ERR}]R_{IV}

As before, substitute V_{LOAD}≈V₁−V_{ERR} and regroup terms:

V_{LOAD}=gₘ₁(V_{P}−V_{N})R_{IV}+gₘ₂V_{ERR}R_{IV}−V_{ERR}

Therefore, just as in FIGS. 3 and 5, setting gₘ₂=1/R_{IV} cancels any V_{ERR} terms in the load voltage.

Although FIG. 7 does not explicitly show this implementation, the output stage correction can also be realized with a unity gain buffer and current mirror as in FIGS. 4 and 6. Here as well, setting R_{EC}=R_{IV} will cancel any V_{ERR} terms in the load voltage.

Thus, in some embodiments, a linear amplifier 30, 36, 38, 48, 52, 54 includes an input stage 12, 50 configured to produce an output current proportional to a first differential input signal. The linear amplifier 30, 36, 38, 48, 52, 54 includes a current-to-voltage resistor 14 in signal communication with the input stage 12, 50, the current-to-voltage resistor 14 configured to receive the output current from the input stage 12, 50 and convert the output current into an amplified signal voltage. The linear amplifier 30, 36, 38, 48, 52, 54 includes a first unity gain voltage buffer in signal communication with the current-to-voltage resistor 14, the first unity gain voltage buffer 16 configured to receive the amplified signal voltage from the current-to-voltage resistor 14 and produce a buffered amplified signal voltage. The linear amplifier 30, 36, 38, 48, 52, 54 includes a high current output stage 18 in signal communication with the first unity gain voltage buffer 16, the high current output stage 18 configured to receive the buffered amplified signal voltage from the first unity gain voltage buffer 16 and to output a load voltage in response to the buffered amplified signal voltage, there being a first voltage drop across the high current output stage 18. The linear amplifier 30, 36, 38, 48, 52, 54 also includes an output correction circuit 32, 40 configured to receive, as a differential input voltage, the first voltage drop across the high current output stage 18, and to output an error current to the current-to-voltage resistor 14 to compensate for the first voltage drop across the high current output stage 18.

In some embodiments, the output correction circuit 32 includes a first operational transconductance amplifier 34 configured to receive the first voltage drop across the high current output stage 18 and to output the error current. In some embodiments, the error current is equal to a transconductance of the first operational transconductance amplifier 34 times the first voltage drop across the high current output stage 18. In some embodiments, a gain of the operational transconductance amplifier 34 is a reciprocal of a resistance of the current-to-voltage resistor 14. In some embodiments, the output correction circuit 40 includes: a second unity gain voltage buffer 42 in signal communication with the first unity gain buffer 16, the second unity gain voltage buffer 42 configured to receive the buffered amplified signal voltage. The output correction circuit 40 includes an error current resistor 46 configured to connect an output of the second unity gain voltage buffer 42 to the output of the high current output stage 18, the error current resistor 46 having an error current proportional to the first voltage drop across the high current output stage 18. The output correction circuit 40 includes a current mirror 44 in signal communication with the second unity gain voltage buffer 42, the current mirror 44 configured to mirror the error current and output a mirrored error current to the current-to-voltage resistor 14. In some embodiments, the input stage includes a negative voltage feedback circuit 56 configured to provide a compensated differential voltage input to the operational transconductance amplifier 12. The negative voltage feedback circuit 56 includes first and second input series resistors 58, 60 configured to receive respective voltage inputs. The negative voltage feedback circuit 56 includes a feedback resistor 24 configured to feedback a signal from an output of the high current output stage 18 to an inverting input of the operational transconductance amplifier 12. The negative voltage feedback circuit 56 includes a gain matching resistor 62 to develop a voltage at a noninverting input of the operational transconductance amplifier 12.

In some embodiments, a resistance of the error current resistor 46 is equal to a resistance of the current-to-voltage resistor 14. In some embodiments, the linear amplifier 30, 36, 38, 48, 52 includes feedback circuitry configured to connect the output of the high current output stage 18 to provide a feedback current to the current-to-voltage resistor 14 to compensate for nonlinearity in the input stage 12, 50 and to compensate for a second voltage drop across the first unity gain voltage buffer 16 and the high current output stage 18. In some embodiments, the feedback circuitry comprises a feedback resistor 24 configured to develop a feedback current proportional to the load voltage, and a current conveyor 26 configured to deliver the feedback current to the current-to-voltage resistor 14. In some embodiments, the input stage 12 includes a first operational transconductance amplifier. In some embodiments, the input stage 50 includes a differential current conveyor and the linear amplifier 48, 52 includes feedback circuitry configured to provide a feedback current from the output of the high current output stage 18 to the differential current conveyor 50. In some embodiments, the differential current conveyor 50 has multiple inputs.

In some embodiments, a linear amplifier 30, 36, 38, 48, 52, 54 includes a high current output stage 18 configured to produce an output current to deliver power to a load. The linear amplifier 30, 36, 38, 48, 52, 54 includes an output correction circuit 32, 40 in signal communication with the high current output stage 18, the output correction circuit 32, 40 configured to receive the output current from the high current output stage 18 and produce an error current proportional to a voltage drop across the high current output stage 18. The linear amplifier 30, 36, 38, 48, 52, 54 includes an input stage 12, 50 configured to receive at least one input and produce a first input current. The linear amplifier 30, 36, 38, 48 52, 54 includes a current-to-voltage resistor 14 configured to receive the first input current and the error current and produce a first voltage that depends on the first input current and the error current. The linear amplifier 30, 36, 38, 48, 52, 54 also includes a first unity gain voltage buffer 16 in signal communication with the input stage 12, 50 and configured to receive the first voltage from the current-to-voltage resistor 14 and to output a second voltage that is input to the high current output stage 18, the first voltage being compensated by the error current to reduce the voltage drop across the high current output stage 18 to zero.

In some embodiments, the output correction circuit 32 includes a transconductance amplifier 34 configured to receive the voltage drop across the high current output stage 18 and output the error current. In some embodiments, the output correction circuit 40 includes: a second unity gain voltage buffer 42 in signal communication with the first unity gain voltage buffer 16, the second unity gain voltage buffer 42 configured to receive the second voltage from the first unity gain voltage buffer 16 and output the error current; and a current mirror 44 in signal communication with the second unity gain voltage buffer 42, the current mirror 44 configured to mirror the error current and output a mirrored error current to the current-to-voltage resistor 14 and to the second unity gain buffer 42. In some embodiments, the linear amplifier 38, 52 includes an error current resistor 46 configured to connect an output of the second unity gain buffer 42 to the output of the high current output stage 18 and wherein the second unity gain buffer 42 is configured to provide the error current to the error current resistor 46.

In some embodiments, a linear amplifier 30, 36, 38, 48, 52, 54 includes an input stage 12, 50, followed by a first unity gain buffer 16, followed by a high current output stage 18 configured to deliver power to a load. The linear amplifier 30, 36, 38, 48, 52, 54 includes an output correction circuit 32, 40. The output correction circuit 40 includes a second unity gain buffer 42 in signal communication with the first unity gain buffer 16, the second unity gain buffer 42 configured to receive an output of the first unity gain buffer 16 and to deliver an error current. The output correction circuit 40 includes a current mirror 44 in signal communication with the second unity gain buffer 42, the current mirror 44 configured to mirror the error current and deliver the mirrored error current to an input of the first unity gain buffer 16 to compensate for a voltage drop across the high current output stage 18.

In some embodiments, the linear amplifier 38, 52 includes an error current resistor 46 in signal communication with an output of the high current output stage 18, the error current resistor 46 configured to provide an error current proportional to the error voltage. In some embodiments, a resistance of the error current resistor 46 is equal to a resistance of a current-to-voltage resistor 14 configured to convert an output current of the input stage 12, 50 to an input voltage to the first unity gain buffer 16. In some embodiments, the error current is added to the output current of the input stage 12, 50.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope of the following claims.

What is claimed is:

1. A linear amplifier for audio amplification, the linear amplifier comprising:
an input stage configured to produce an output current proportional to a first differential input signal;
a current-to-voltage resistor in signal communication with the input stage, the current-to-voltage resistor configured to receive the output current from the input stage and convert the output current into an amplified signal voltage;
a first unity gain voltage buffer in signal communication with the current-to-voltage resistor, the first unity gain voltage buffer configured to receive the amplified signal voltage from the current-to-voltage resistor and produce a buffered amplified signal voltage;
a high current output stage in signal communication with the first unity gain voltage buffer, the high current output stage configured to receive the buffered amplified signal voltage from the first unity gain voltage buffer and to output a load voltage in response to the buffered amplified signal voltage, there being a first voltage drop across the high current output stage; and
an output correction circuit configured to receive, as a differential input voltage, the first voltage drop across the high current output stage, and to output an error current to the current-to-voltage resistor to compensate for the first voltage drop across the high current output stage.

2. The linear amplifier of claim 1, wherein the output correction circuit includes a first operational transconductance amplifier configured to receive the first voltage drop across the high current output stage and to output the error current.

3. The linear amplifier of claim 2, wherein the error current is equal to a transconductance of the first operational transconductance amplifier times the first voltage drop across the high current output stage.

4. The linear amplifier of claim 3, wherein a transconductance of the operational transconductance amplifier is a reciprocal of a resistance of the current-to-voltage resistor.

5. The linear amplifier of claim 1, wherein the output correction circuit includes:
a second unity gain voltage buffer in signal communication with the first unity gain buffer, the second unity gain voltage buffer configured to receive the buffered amplified signal voltage;
an error current resistor configured to connect an output of the second unity gain voltage buffer to the output of the high current output stage, the error resistor having an error current proportional to the first voltage drop across the high current output stage; and
a current mirror in signal communication with the second unity gain voltage buffer, the current mirror configured to mirror the error current and output a mirrored error current to the current-to-voltage resistor.

6. The linear amplifier of claim 5, wherein a resistance of the error current resistor is equal to a resistance of the current-to-voltage resistor.

7. The linear amplifier of claim 1, further comprising feedback circuitry configured to connect the output of the high current output stage to provide a feedback current to the current-to-voltage resistor to compensate for nonlinearity in the input stage and to compensate for a second voltage drop across the first unity gain voltage buffer and the high current output stage.

8. The linear amplifier of claim 7, wherein the feedback circuitry comprises a feedback resistor configured to develop a feedback current proportional to the load voltage, and a current conveyor configured to deliver the feedback current to the current-to-voltage resistor.

9. The linear amplifier of claim 8, wherein a resistance of the error current resistor is equal to a resistance of the current-to-voltage resistor.

10. The linear amplifier of claim 1, wherein the input stage includes a first operational transconductance amplifier.

11. The linear amplifier of claim 1, wherein the input stage includes a differential current conveyor and the linear amplifier includes feedback circuitry configured to provide a feedback current from the output of the high current output stage to the differential current conveyor.

12. The linear amplifier of claim 7, wherein the differential current conveyor has multiple inputs.

13. A linear amplifier for audio amplification, the linear amplifier comprising:
a high current output stage configured to produce an output current to deliver power to a load;
an output correction circuit in signal communication with the high current output stage, the output correction circuit configured to receive the output current from the high current output stage and produce an error current proportional to a voltage drop across the high current output stage;
an input stage configured to receive at least one input and produce a first input current;
a current-to-voltage resistor configured to receive the first input current and the error current and produce a first voltage that depends on the first input current and the error current; and
a first unity gain voltage buffer in signal communication with the input stage and configured to receive the first voltage from the current-to-voltage resistor and to output a second voltage that is input to the high current output stage, the first voltage being compensated by the error current to reduce the voltage drop across the high current output stage to zero.

14. The linear amplifier of claim 13, wherein the output correction circuit includes a transconductance amplifier configured to receive the voltage drop across the high current output stage and output the error current.

15. The linear amplifier of claim 13, wherein the output correction circuit includes:
a second unity gain voltage buffer in signal communication with the first unity gain voltage buffer, the second unity gain voltage buffer configured to receive the second voltage from the first unity gain voltage buffer and output the error current; and
a current mirror in signal communication with the second unity gain voltage buffer, the current mirror configured to mirror the error current and output a mirrored error current to the current-to-voltage resistor and to the first unity gain buffer.

16. The linear amplifier of claim 15, further comprising an error current resistor configured to connect an output of the second unity gain buffer to the output of the high current output stage and wherein the second unity gain buffer is configured to provide the error current to the error current resistor.

17. A linear amplifier for audio amplification, the linear amplifier including an input stage, followed by a first unity gain buffer, followed by a high current output stage configured to deliver power to a load, the linear amplifier further comprising an output correction circuit, the output correction circuit comprising:
a second unity gain buffer in signal communication with the first unity gain buffer, the second unity gain buffer configured to receive an output of the first unity gain buffer and to deliver an error current; and
a current mirror in signal communication with the second unity gain buffer, the current mirror configured to mirror the error current and deliver the mirrored error current to an input of the first unity gain buffer to compensate for a voltage drop across the high current output stage.

18. The linear amplifier of claim 17, further comprising an error current resistor in signal communication with an output of the high current output stage, the error current resistor configured to provide an error current proportional to the error voltage.

19. The linear amplifier of claim 18, wherein a resistance of the error current resistor is equal to a resistance of a current-to-voltage resistor configured to convert an output current of the input stage to an input voltage to the first unity gain buffer.

20. The linear amplifier of claim 19, wherein the error current is added to the output current of the input stage.
